(19) United States
(12) Patent Application Publication
(10) Pub. No.: US 2006/0157345 A1
(43) Pub. Date: Jul. 20, 2006

(54) In-line coating/sputtering system with internal static electricity/dust removal and recycle apparatuses

(75) Inventors: Tai-Yuan Huang, Yunlin County (TW); Hsueh-Chiung Liao, Taichung Country (TW); Tuan-Jen Yu, Taichung Country (TW); Chung-Chung Liu, Taichung Country (TW); Yuan-Chi Lee, Taichung Country (TW); Geeng-Jen Sheu, Taichung City (TW)

Correspondence Address: BIRCH STEWART KOLASCH & BIRCH, PO BOX 747, FALLS CHURCH, VA, 22040-0747, US

(73) Assignee: UVAT Technology Co., LTd.

(21) Appl. No.: 11/331,034

(22) Filed: Jan. 13, 2006

(30) Foreign Application Priority Data
Jan. 20, 2005 (TW) 94101706

(51) Int. Cl. C23C 14/00

(52) U.S. Cl. 204/298.02

(57) ABSTRACT

An in-line coating/sputtering system includes a clean region with an internal static electricity/dust removal apparatus and an elevator device therein. A loading region has a pressure-down chamber with two gates on opposite ends thereof, one of which is communicated with the clean region. A coating/sputtering region has a vacuum chamber with two gates on opposite ends thereof, one of which is communicated with the pressure-down chamber of the loading region. An unloading region has a pressure-up chamber with two gates on opposite ends thereof, one of which is communicated with the vacuum chamber of the coating/sputtering region. A rear reversible region has an open chamber communicated with the pressure-up chamber of the unloading region, in which an elevator device is provided. A return region having a channel connecting the rear reversible region and the clean region, in which a backward transmission device is provided.

### BACKGROUND OF THE INVENTION

1. Field of the Invention

The present invention relates generally to a coating/sputtering system, and more particularly to an in-line vacuum coating/sputtering system with internal static electricity/dust removal and recycle apparatuses.

2. Description of the Related Art

The conventional in-line coating/sputtering system is consisted at least one loading chamber, one process chamber for reactive magnetron coating/sputtering, and one unloading chamber. The substrates usually are placed on a carrier for translation, and then delivered into the loading chamber. When the coating/sputtering process is finished, the products are taken out from the unloading chamber, and the carrier is returned to the loading chamber by way of the external recycle apparatus for the next batch. However, the quality highly demands on the cleanness of the transport process and the static electricity of the substrates. If any suspension or dust adheres on the surface of substrates during the transport process, it will cause undesired optical character, unusual convexity or exceptional penetrability, and affect the quality of the products. Moreover, if the substrates with the capacity of static electricity, not only the bonding force and uniformity of the coating/sputtering surfaces, but also the optical characteristics and electrical functions of the products are affected. Therefore, the substrates and carrier are usually dealt and pre-treated with external static electricity and dust removal apparatuses to remove dust and static electricity in advance of the in-line coating/sputtering system. However, there are at least three serious problems for the conventional process.

Firstly, after the clean pre-treatment procedure in the external dust removal apparatus, the substrates and carrier are taken out of the apparatus, and wait for the coating/sputtering process. During the waiting stage, the substrates and carrier expose in an open atmosphere environment that will pollute the substrates and carrier again. The longer the waiting time, the more the amount of the pollution. Besides, at least one additional operator is required for the connection and transport between the clean pre-treatment procedure and the in-line coating/sputtering system. The fingerprints of the operator will be involved on the surfaces of the substrates/carrier in the transport process. These drawbacks make the external clean pre-treatment fail to produce the expected effect. On the other hand, the external static electricity removal apparatus faces the same problems.

Secondly, the conventional external cleanness procedure only removes the dust and static electricity on the top of the substrates and the carrier effectively, however, the dust and static electricity on the lateral side and bottom will still exist. As a result, there still is some dust and static electricity on the substrates and carrier when they are delivered into the in-line coating/sputtering system. It will affect the quality and yield of the products. After a predetermined period, the suspension and dust will be deposited and adhere on the surface of the vacuum chambers, hence pollute the cleanness. It affects the cleanness and of the vacuum chambers. The system then needs to periodically shut down to maintain and clear the chambers. It will reduce the activation of system and the efficiency of production.

Thirdly, the layout of the conventional external recycle apparatus is usually horizontal “Π38 type to achieve the closed loop system with the in-line coating/sputtering system. As a result, not only triple or more additional space will be occupied for the factory, but also the dust will adhere on the surface of the carrier and pollute again because the external recycle apparatus exposes in an open atmosphere environment, not in an isolated condition.

### SUMMARY OF THE INVENTION

The primary objective of the present invention is to provide an in-line coating/sputtering system with internal static electricity/dust removal and recycle apparatuses to improve the cleanness of the transport process and reduce the occupied space of the recycle system effectively.

According to the objective of the present invention, an in-line coating/sputtering system integrates a clean region in the front of the in-line coating/sputtering system, in which an internal static electricity/dust removal apparatus and an elevator device are provided. A loading region has a pressure-down chamber with two gates on opposite ends thereof. One of the gates is communicated with the clean region. A coating/sputtering region has a vacuum chamber with two gates on opposite ends thereof. One of the gates is communicated with the pressure-down chamber of the loading region. An unloading region has a pressure-up chamber with two gates on opposite ends thereof. One of the gates is communicated with the vacuum chamber of the coating/sputtering region. A rear reversible region has an open chamber communicated with the pressure-up chamber of the unloading region, in which an elevator device is provided. A return region has a channel to connect the rear reversible region and the clean region, in which a backward transmission device is provided. The return region is located under the loading region, the coating/sputtering region and the unloading region, hence no additional space is occupied.

### BRIEF DESCRIPTION OF THE DRAWINGS

FIG. 1 is a sketch diagram of the first preferred embodiment of the present invention; and

FIG. 2 is a sketch diagram of the second preferred embodiment of the present invention.

### DETAILED DESCRIPTION OF THE INVENTION

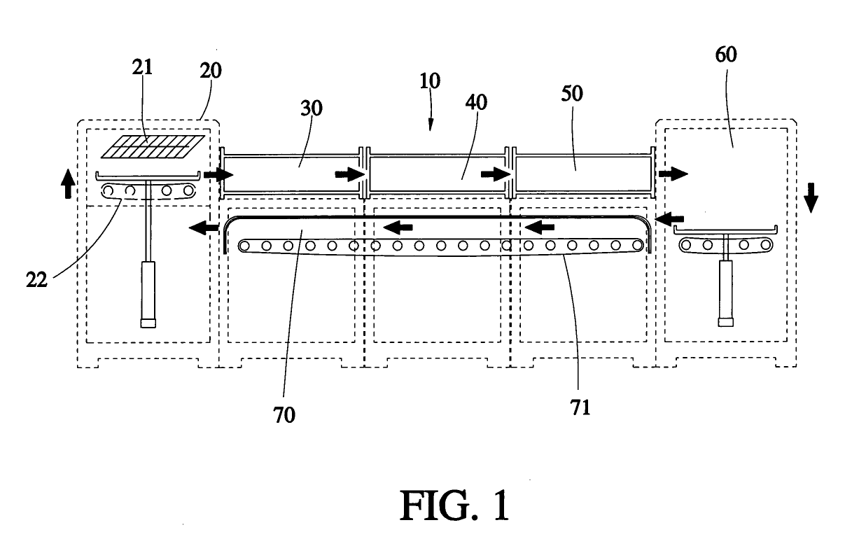

As shown in FIG. 1, an in-line coating/sputtering system 10 of the first preferred embodiment of the present invention comprises:

A clean region 20, which is integrated in the front of the in-line coating/sputtering system 10, is consisted of an internal static electricity/dust removal apparatus 21 and an elevator device 22.

A loading region 30, which is a pressure-down chamber with two gates on opposite ends thereof, is used to achieve an expected vacuum condition gradually, prior to the next coating/sputtering procedure. One of the gates is communicated with the chamber of the clean region 20.

A coating/sputtering region 40 has a vacuum chamber with two gates on opposite ends thereof, in which the coating/sputtering is accomplished. One of the gates is communicated with the pressure-down chamber of the loading region 30.

An unloading region 50, which is a pressure-up chamber with two gates on opposite ends thereof, is used to recover the atmosphere condition gradually. One of the gates is communicated with the vacuum chamber of the coating/sputtering region 40.

A rear reversible region 60, which is an open chamber consisted of an elevator device 61, is communicated with the pressure-up chamber of the unloading region 50. The substrates and carrier are delivered forward when the elevator device 21 is at upper expected position, but backward at lower expected position.

The present invention further provides a return region 70, which is a channel connecting the rear reversible region 60 and the clean region 20. It is provided with two gates on opposite ends of the channel, and a backward transmission device 71 between the gates. Unlike the conventional external recycle apparatus, the return region 70 is an internal apparatus because it is exactly located under the loading region 30, the coating/sputtering region 40 and the unloading region 50. Consequently, both no additional space is occupied, and dust is difficult to adhere on the surface of substrates/carrier with the isolation effect during the backward transport process.

When the in-line coating/sputtering system 10 of present invention is integrated with the above regions and apparatuses, the coating/sputtering process is consisted of the following steps. Firstly, the operator put the substrates on a carrier in the clean region 20 to remove the dust and static electricity of the substrates in advance. Then, the carrier with the substrates is directly delivered into the loading region 30, the coating/sputtering region 40, the unloading region 50 and the rear reversible region 60 in sequence. When the carrier touches the rear limit switch, the carrier stops and the elevator device 61 goes down until the lower expected position. Then, the carrier with the product is transmitted backward in the return region 70, and then delivered back to the clean region 20. When the carrier touches the front limit switch, the carrier stops and the elevator device 22 goes up until the upper expected position. Finally, the operator takes the product out of the clean region 20 to finish the coating/sputtering process, but the carrier is always kept in the clean region 20 and waits for the next batch. When the next batch of substrates is put on the carrier and delivered, the coating/sputtering process is activated again.

As a result, the substrates are directly delivered to the loading region 30 after cleaning procedure of the clean region 20. Neither exposure in an open atmosphere environment, nor fingerprints of the operator will be involved. It can prevent the substrates and carrier from dust and pollution effectively.

In addition, the operator doesn't have to touch the carrier and take it out every batch when he/she put the substrates or take the product out. The carrier always remains in the chambers of the in-line coating/sputtering system 10 for the coating/sputtering process. Therefore, the carrier is isolated from the open atmosphere environment effectively, and it will reduce the chance of dust to adhere on the surface of carrier, hence improve the cleanness of the transmission process.

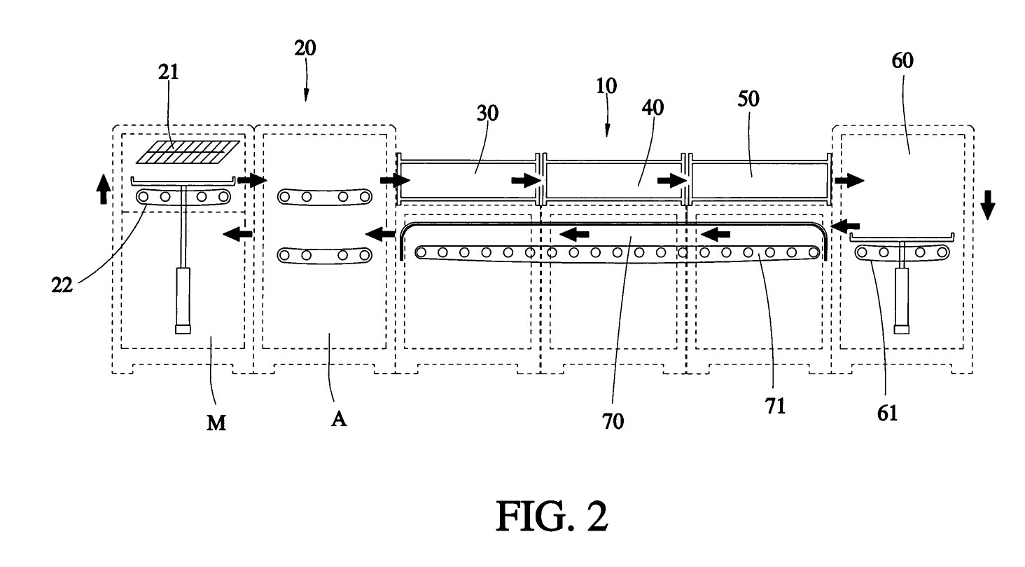

FIG. 2 shows an in-line coating/sputtering system of the second preferred embodiment of the present invention, which is similar to the first preferred embodiment, except that the clean region 20 has two sections, both of which are provided with a static electricity/dust removal apparatus respectively. The first section M is manipulative, and the second section A is automatic. It has the same function as the first preferred embodiment, except for the double cleanness improvement.

What is claimed is:

1. An in-line coating/sputtering system, comprising:
a clean region integrated in a front of the in-line coating/sputtering system, in which an internal static electricity/dust removal apparatus and an elevator device are provided;
a loading region having a pressure-down chamber with two gates on opposite ends thereof, one of which is communicated with the clean region;
a coating/sputtering region having a vacuum chamber with two gates on opposite ends thereof, one of which is communicated with the pressure-down chamber of the loading region;
an unloading region having a pressure-up chamber with two gates on opposite ends thereof, one of which is communicated with the vacuum chamber of the coating/sputtering region;
a rear reversible region having an open chamber communicated with the pressure-up chamber of the unloading region, in which an elevator device is provided; and
a return region having a channel connecting the rear reversible region and the clean region, in which a backward transmission device is provided.

2. The in-line coating/sputtering system as defined in claim 1, further comprising an air-extracting device in the clean region.

3. The in-line coating/sputtering system as defined in claim 1, wherein the clean region has a manipulative clean section.

4. The in-line coating/sputtering system as defined in claim 1, wherein the clean region has an automatic clean section.

5. The in-line coating/sputtering system as defined in claim 1, wherein the clean region has a manipulative clean section and an automatic clean section.

6. The in-line coating/sputtering system as defined in claim 1, wherein the return region has a channel connecting the rear reversible region and the clean region.

7. The in-line coating/sputtering system as defined in claim 6, wherein the return region is provided with two gates on opposite ends of the channel.
